(19) United States
(12) Patent Application Publication
(10) Pub. No.: US 2026/0348786 A1
(43) Pub. Date: Nov. 5, 2026

(54) LIQUID LEAK DETECTION USING A REFLECTOR

(71) Applicant: Dell Products L.P., Round Rock, TX (US)

(72) Inventors: BRENNAN TROY ROBERT SEAL, Austin, TX (US); TREVOR TRENT DAWSON, Austin, TX (US); SANDOR TIBOR FARKAS, Round Rock, TX (US); MICHAEL J. STUMPF, Cedar Park, TX (US); ROBERT WARREN JOHNSON, Round Rock, TX (US); FABIENNE UMUTONIWASE, Hutto, TX (US)

(21) Appl. No.: 19/194,203

(22) Filed: Apr. 30, 2025

(51) Int. Cl. G01M 3/04; H05K 7/20

(52) U.S. Cl. CPC G01M 3/04; H05K 7/20772

(57) ABSTRACT

Devices, systems, and methods for managing leaks in a chassis of a data processing system is provided. To manage the leaks, the data processing system may include an electromagnetic stimulator, a reflector, an electromagnetic detector, and a management component. The electromagnetic stimulator may be adapted to generate first electromagnetic radiation. The reflector may be adapted to collect a portion of a liquid within the chassis, and direct the first electromagnetic radiation to the portion of the liquid to cause the portion of the liquid to generate second electromagnetic radiation. The electromagnetic detector may be adapted measure at least a portion of the second electromagnetic radiation to obtain at least one electromagnetic measurement. The management component may determine whether a liquid leak within the chassis occurred based on the at least one electromagnetic measurement. If the liquid leak occurred, performance of a remediation action may be initiated.

### FIELD

Embodiments disclosed herein relate generally to managing leaks. More particularly, embodiments disclosed herein relate to systems and methods for managing leaks in a chassis of a data processing system using a leak detector.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIGS. 1A-1B show diagrams illustrating a data processing system in accordance with an embodiment.

FIGS. 2A-2C show diagrams illustrating a leak detector in accordance with an embodiment.

FIGS. 3A-3H show diagrams illustrating a reflector in accordance with an embodiment.

FIG. 4 shows a flow diagram illustrating a method for managing leaks in a chassis of a data processing system in accordance with an embodiment.

FIG. 5 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods, systems, and devices for managing operation of a data processing system. The data processing system may provide computer-implemented services. To provide the computer-implemented services, the data processing system may include any number and/or type of hardware components. Operation of the hardware components may facilitate various functionalities of the data processing system, thereby allowing the data processing system to provide the computer-implemented services.

Operation of the hardware components may generate heat. To manage the heat generated by the hardware components so that the hardware components may operate as desired, a liquid cooling system may be used. To do so, a cooling liquid may be circulated within a chassis of the data processing system to dissipate at least a portion of the heat generated by the hardware components.

However, by circulating the cooling liquid through the chassis (and/or otherwise having liquid within the system), a likelihood of liquid damage may be increased within the system. For example, should the liquid cooling system leak at least a portion of the cooling liquid, the hardware components may be vulnerable to liquid damage. Consequently, such liquid damage may negatively impact the operation of the hardware components. In turn, this damage may also negatively impact the computer-implemented services provided by the data processing system.

To mitigate an impact of an occurrence of a liquid leak in the chassis of the data processing system, the data processing system may include functionality to detect liquid leaks using a leak detector. The leak detector may be used to monitor portions of the data processing system which may have a risk of liquid leaks occurring (e.g., connection points of the cooling tubes). To do so, the leak detector may include: (i) an electromagnetic stimulator adapted to generate first electromagnetic radiation, (ii) a reflector, (iii) an electromagnetic detector adapted to measure second electromagnetic radiation (e.g., generated by a portion of the liquid in response to illumination by the first electromagnetic radiation), and/or (iv) a management component.

The reflector may be adapted to: (i) collect the portion of the liquid within the chassis, and (ii) direct the first electromagnetic radiation to the portion of the liquid. For example, the data processing system may include an airflow control component (e.g., a cooling fan) which generates an airflow within the chassis. The airflow may entrain an aerosolized portion of liquid, which may condense on the reflector. The reflector may then direct the portion of the liquid to a predetermined location (e.g., on a reflective wall of the reflector, on a portion of a floor of the chassis, etc.). The reflector may then direct the first electromagnetic radiation to the portion of the liquid.

By doing so, a likelihood that the first electromagnetic radiation illuminates the portion of the liquid in a manner that causes the portion of the liquid to generate second electromagnetic radiation may be improved. At least a portion of the second electromagnetic radiation may be measured by the electromagnetic detector to obtain at least one electromagnetic measurement, which may be used by the management component to determine whether the liquid leak occurred.

Thus, embodiments disclosed herein may provide an improved data processing system that may have an improved likelihood of detecting a liquid leak within a chassis of the data processing system. By detecting the leak, additional leaked cooling liquid may be prevented from escaping into an interior of the chassis. Consequently, the hardware components may operate as desired, and computer-implemented services may be reliably provided by the data processing system using the hardware components.

In an embodiment, a data processing system is provided. The data processing system may include: a chassis; an electromagnetic stimulator adapted to generate first electromagnetic radiation; a reflector adapted to: collect a portion of a liquid within the chassis, and direct the first electromagnetic radiation to the portion of the liquid, the first electromagnetic radiation being adapted to cause the portion of the liquid to generate second electromagnetic radiation; an electromagnetic detector adapted to: measure at least a portion of the second electromagnetic radiation to obtain at least one electromagnetic measurement; and a management component adapted to: make a determination regarding whether a liquid leak within the chassis has occurred based on the at least one electromagnetic measurement; and in an instance of the determination where the liquid leak has occurred: initiate performance of a remediation action to mitigate impacts of the liquid leak.

The reflector may be positioned with respect to the electromagnetic stimulator and the electromagnetic detector to prevent direct illumination of the electromagnetic detector by the first electromagnetic radiation.

The reflector may include at least one reflective wall.

The at least one reflective wall may include at least one opening, and the at least one opening may be adapted to: allow an airflow to pass through the at least one reflective wall; and transmit a predetermined portion of the first electromagnetic radiation so that a reflected portion of the first electromagnetic radiation meets a minimum threshold level, the reflected portion being incident on the portion of the liquid.

The at least one reflective wall may include a curved surface adapted to distribute two portions of the first electromagnetic radiation to two different regions within the chassis, the two different regions being physically separated from each other.

The at least one reflective wall may be adapted to: condense the portion of the liquid on the at least one reflective wall; and direct the portion of the liquid to a predetermined location to collect the portion of the liquid.

The predetermined location may be positioned with respect to the electromagnetic stimulator and the electromagnetic detector to: receive the first electromagnetic radiation; and direct the at least the portion of the second electromagnetic radiation generated by the portion of the liquid to the electromagnetic detector.

The at least one reflective wall may include at least one opening adapted to cause the portion of the liquid to condense on at least edges of the at least one opening.

The reflector may include a plurality of reflective walls, and the plurality of reflective walls may be arranged to partially enclose a three-dimensional space around the electromagnetic stimulator and the electromagnetic detector.

The plurality of reflective walls may be adapted to direct the portion of the liquid to the predetermined location within the three-dimensional space.

The data processing system may also include: a liquid cooling block adapted to cool a hardware component using the liquid, wherein the portion of the liquid is aerosolized during the collecting by the reflector.

The data processing system may also include: an airflow control component adapted to generate an airflow through the chassis, the airflow entraining the aerosolized portion of the liquid, and the airflow traversing proximate to the reflector.

In an embodiment, a method for managing leaks in a chassis of a data processing system is provided.

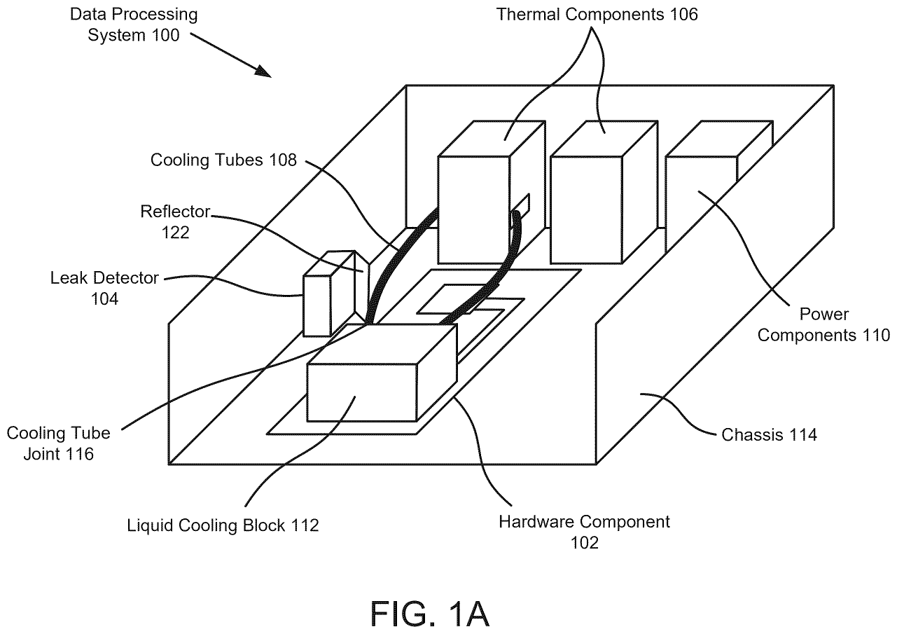

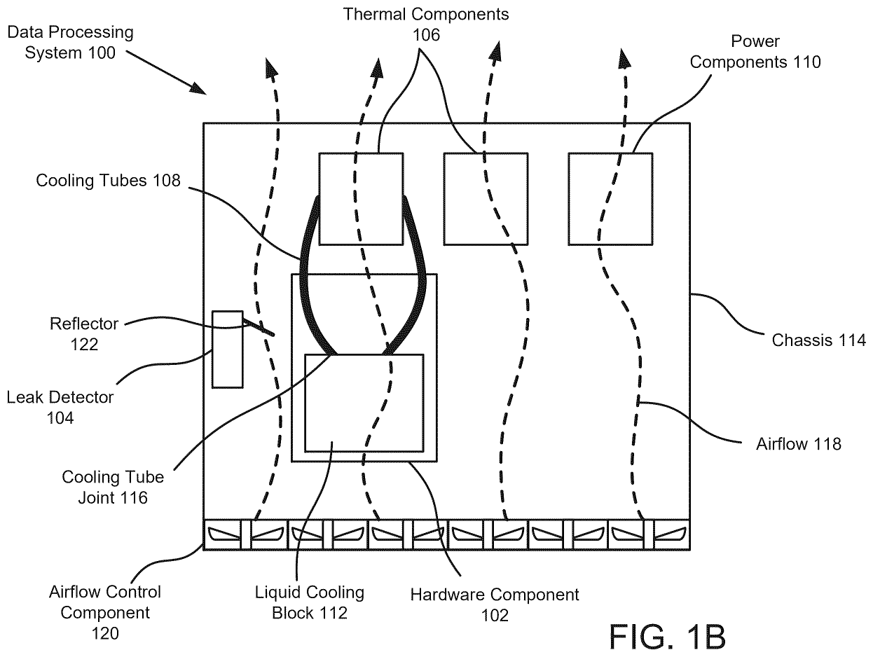

Turning to FIGS. 1A-1B, block diagrams illustrating a system in accordance with an embodiment are shown. FIG. 1A may show an isometric view of the system. FIG. 1B may show a top view of the system.

The system shown in FIGS. 1A-1B may provide any quantity and type of computer-implemented services. To provide the computer-implemented services, the system of FIGS. 1A-1B may include data processing system 100.

Data processing system 100 may include functionality to provide various types of computer-implemented services. The computer-implemented services may include any number and type of computer-implemented services. The computer-implemented services may include, for example, database services, data processing services, electronic communication services, and/or any other services that may be provided using one or more computing devices. Other types of computer-implemented services may be provided by data processing system 100 without departing from embodiments disclosed herein.

To provide the computer implemented services, data processing system 100 may include any number of hardware components. For example, operation of the any number of hardware components may facilitate various functionalities of data processing system 100, thereby allowing data processing system 100 to provide the computer-implemented services. The hardware components of data processing system 100 may include, for example, hardware component 102, power components 110, and/or thermal components 106. Each of these components is discussed below.

Hardware component 102 may include at least a portion of the any number of hardware components (e.g., a central processing unit, a graphics processing unit, memory, etc.), and as noted above, may provide computer-implemented services. Hardware component 102 may be positioned on circuit cards (e.g., pieces of circuit boards), and may generate heat while operating.

Hardware component 102 and/or any other components of the any number of hardware components of data processing system 100 may be positioned in chassis 114. Chassis 114 may include an enclosure in which physical structures of hardware components (e.g., processors, memory, etc.), and/or other components of data processing system 100 may be positioned. For example, chassis 114 may facilitate placement and management of hardware component 102 and/or other components (e.g., power components 110 and/or thermal components 106) in a computing environment such as those discussed below.

Power components 110 may power the any number of hardware components of data processing system 100. For example, power components 110 may be implemented using power supplies. Operation of these power supplies may also contribute to the generation of heat. If left unregulated, this generation of heat may increase the likelihood of damage to data processing system 100.

For example, any of the components of data processing system 100 (e.g., hardware component 102) may have thermal dissipation requirements that must be met for the components to operate nominally (e.g., with low probability of error, low chance of damage/failure, etc.). The thermal dissipation requirements may include, for example, an optimal temperature range for operation, and/or other requirements.

The heat generated by the various components may be managed to meet the thermal dissipation requirements and reduce the likelihood of damage to data processing system 100. To do so, data processing system 100 may include an air cooling system and/or a liquid cooling system that is at least partially housed by chassis 114. The air cooling system may be implemented using any number of cooling components, such as airflow control component 120 shown in FIG. 1B. Airflow control component 120 may include a fan (and/or another system to circulate air through the data processing system). Airflow control component 120 may generate an airflow (e.g., airflow 118 shown in FIG. 1B) to cool the various components, such as hardware component 102, at prescribed rates. Airflow 118 may be directed along an airflow path, the airflow path beginning at a first side of data processing system 100 and ending at a second side of data processing system 100.

To further improve the likelihood of meeting the thermal dissipation requirements of the various components, data processing system may include the liquid cooling system (e.g., in addition to the air cooling system). This liquid cooling system may include any number of cooling components such as thermal components 106, cooling tubes 108, liquid cooling block 112, and/or any other cooling components not shown in the system of FIGS. 1A-1B.

Thermal components 106 may thermally manage any of the components of data processing system 100. For example, thermal components 106 may include thermal components such as coolant reservoirs and/or receiving elements for coolant, coolant (e.g., a cooling fluid), circulation pumps, manifolds or other types of flow control components, and/or other components to facilitate performance of liquid-based cooling of at least some of the various components, such as hardware component 102. For example, thermal components 106 may be used with cooling tubes 108 and liquid cooling block 112, each of which is discussed below.

Liquid cooling block 112 may be adapted to cool the various components, for example hardware component 102, using a liquid such as a cooling liquid (e.g., coolant). To do so, liquid cooling block 112 may circulate the cooling liquid via cooling tubes 108. To provide its functionality, liquid cooling block 112 may operate as a heat sink for some hardware components (e.g., hardware component 102). For example, liquid cooling block 112 may be placed with hardware component 102 to: (i) receive heat generated by hardware component 102, and (ii) dissipate the received heat into the cooling liquid circulated through liquid cooling block 112. While providing its functionality, a transference of at least a portion of the generated heat may be facilitated.

For example, the cooling liquid may be confined to a flow path that circulates through a loop of a liquid cooling system (e.g., cooling tubes 108, liquid cooling block 112, external components such as large-scale coolant chillers, flow controllers, etc.). The flow path may be placed in thermal communication with hardware component 102, which may be generating the heat when the cooling liquid is flowing through a portion of the loop that is proximate to hardware component 102. By being in this thermal communication, the cooling liquid may be heated while the heat generated by hardware component 102 is dissipated into the cooling liquid, thereby regulating the temperature of hardware component 102.

The heated cooling liquid circulating through liquid cooling block 112 may then flow to another portion of the loop (e.g., external to data processing system 100, such as a large-scale chiller/heat exchanger, not shown) in order to be cooled. Thus, the cooling liquid may be cyclically heated and cooled as the cooling liquid continues to flow through the loop, thereby contributing to the dissipation of heat generated by hardware component 102. As a result, the thermal dissipation requirements of hardware component 102 may be met.

For example, the cooling liquid may be directed through an interior of liquid cooling block 112 and through a first portion of cooling tubes 108. Cooling tubes 108 may further facilitate the circulation by directing the cooling liquid, for example, to other cooling blocks proximate to other hardware components of data processing system 100. In doing so, cooling of multiple hardware components may be facilitated. To do so, cooling tubes 108 may include hollow, tubular structures in which liquid may flow through. For example, the cooling liquid, once cooled by external chillers, may then be further circulated through a second portion of cooling tubes 108 to direct the cooling liquid back through the liquid cooling block 112 to facilitate transference of additional heat generated by hardware component 102 and/or any other hardware components.

However, by using the liquid cooling system discussed above, a likelihood of physically damaging the any number of hardware components (e.g., should a leak in liquid cooling block 112 and/or cooling tubes 108 occur) may be increased due to the presence of the cooling liquid. For example, if liquid cooling block 112 and/or cooling tubes 108 begin to leak, at least a portion of the cooling liquid may no longer be confined to the flow path that circulates through the loop of the liquid cooling system.

As a result of the leak, a portion of the cooling liquid may be aerosolized. For example, due to the presence of airflow 118 within chassis 114, particles of the cooling liquid may become suspended in the moving stream of air. Thus, airflow 118 may entrain the aerosolized particles of cooling liquid, which may increase a likelihood of damage to the any number of hardware components (e.g., due to exposure to the cooling liquid). Consequently, functionality of the any number of hardware components may be negatively impacted, thereby negatively impacting an ability of data processing system 100 to provide the computer-implemented services. Further, continued operation of airflow control component 120 may spray the leaked cooling liquid throughout chassis 114 and/or out of chassis 114 (e.g., through air vents and/or other openings in chassis 114), which may result in damage to any other devices outside of chassis 114.

In general, embodiments disclosed herein may provide methods, systems, and/or devices for managing leaks in a chassis of a data processing system to improve a likelihood that the data processing system is able to provide its computer-implemented services. To improve the likelihood that data processing system 100 is able to provide its computer-implemented services, data processing system 100 may include functionality to detect leaks using a leak detector (e.g., leak detector 104).

Leak detector 104 may be positioned internal to data processing system 100 and may be used to monitor portions of data processing system 100, such as portions in which leaks may occur (e.g., portions of data processing system 100 in which leaks are more likely to occur compared to other portions of data processing system 100). For example, leaks of the cooling liquid may occur at connection points of cooling tubes 108, such as cooling tube joint 116. Cooling tube joint 116 may include any type of connector and/or fitting used to connect a portion of cooling tube 108 to liquid cooling block 112. During operation of the liquid-cooling system over time, cooling tube joint 116 may fail to maintain a seal between the portion of cooling tube 108 and liquid cooling block 112. For example, cooling tube joint 116 may fail due to corrosion, wear and tear, improper installation, damage, and/or other reasons. As a result, the cooling liquid may begin to leak.

To detect the leak, therefore limiting damage to various components of data processing system 100 due to contact with the cooling liquid, leak detector 104 may include: (i) an electromagnetic stimulator, (ii) an electromagnetic detector, (iii) a reflector (e.g., 122), and/or (iv) a management component. The electromagnetic stimulator may be adapted to generate first electromagnetic radiation. The first electromagnetic radiation may be adapted to cause a portion of a liquid (e.g., a portion of leaked cooling liquid) within chassis 114 to generate second electromagnetic radiation. The electromagnetic detector may be adapted to measure at least a portion of the second electromagnetic radiation to obtain at least one electromagnetic measurement. The at least one electromagnetic measurement may be used by the management component to determine whether the liquid leak has occurred. If the liquid leak has occurred, performance of a remediation action may be initiated to mitigate impacts of the liquid leak.

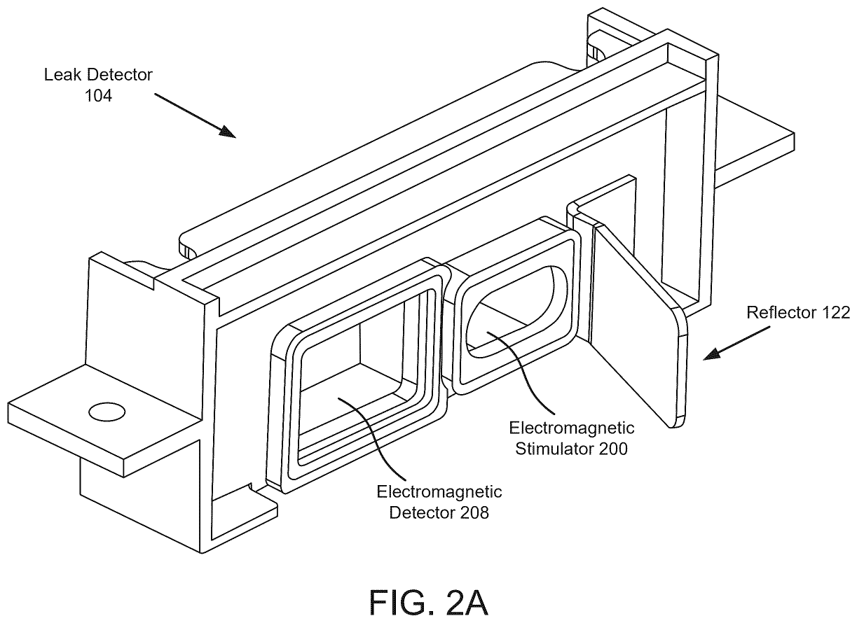

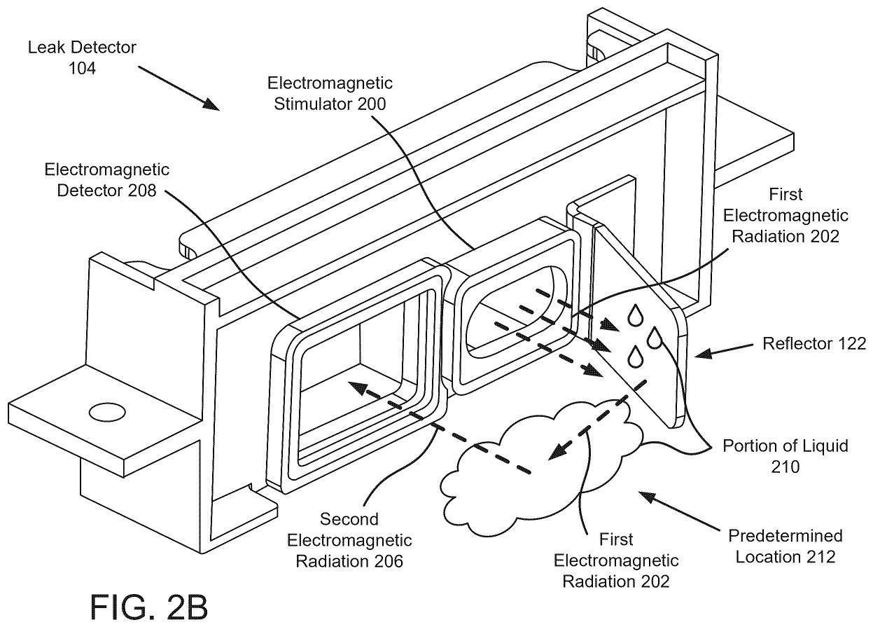

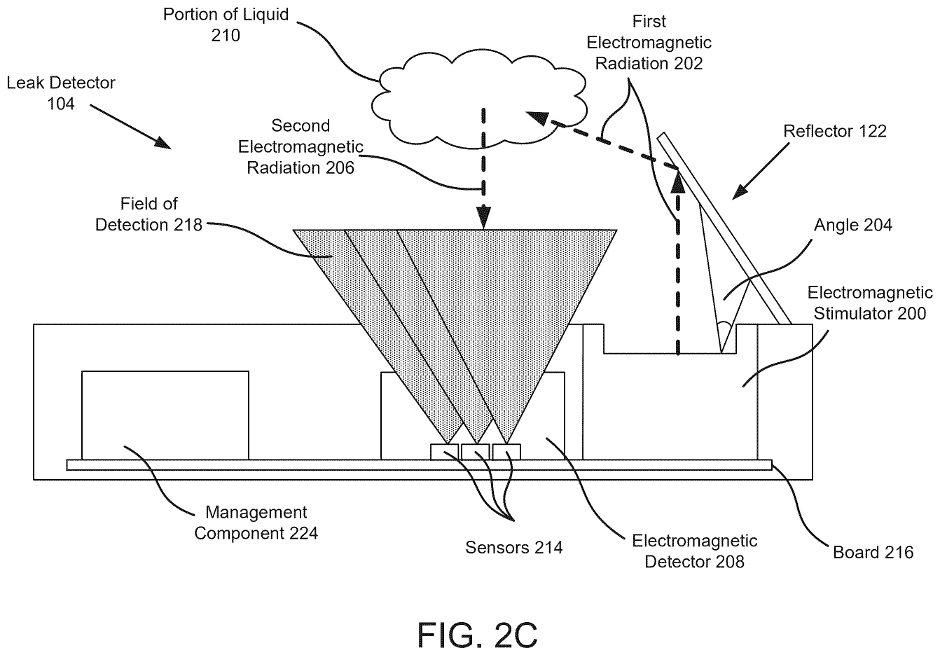

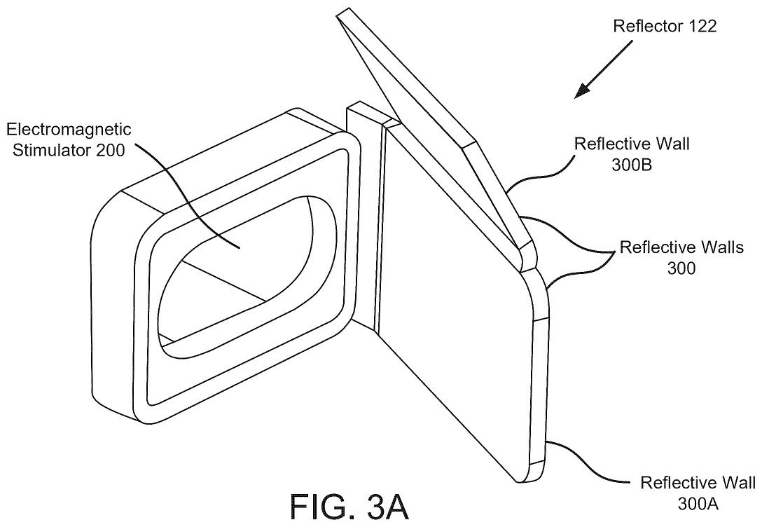

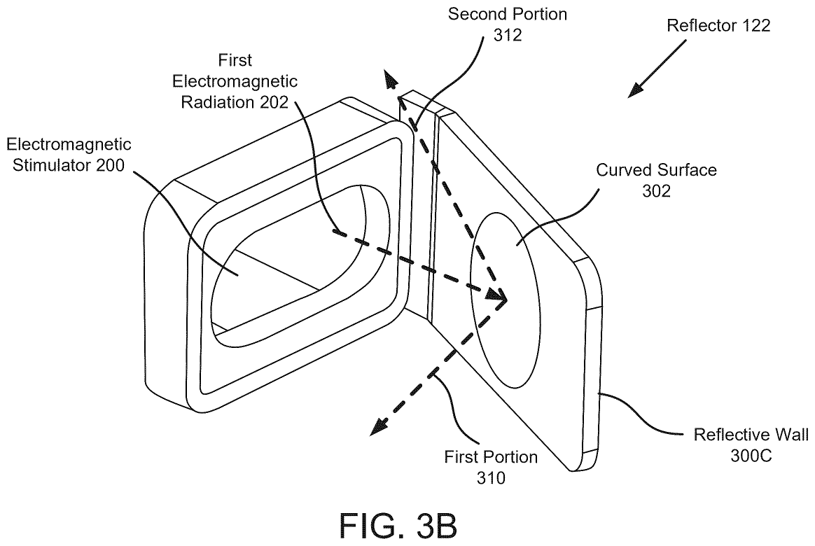

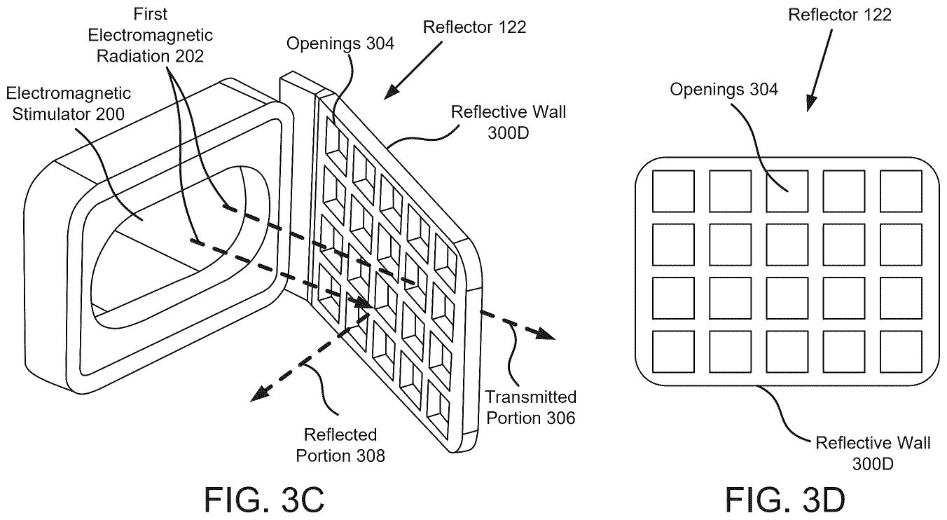

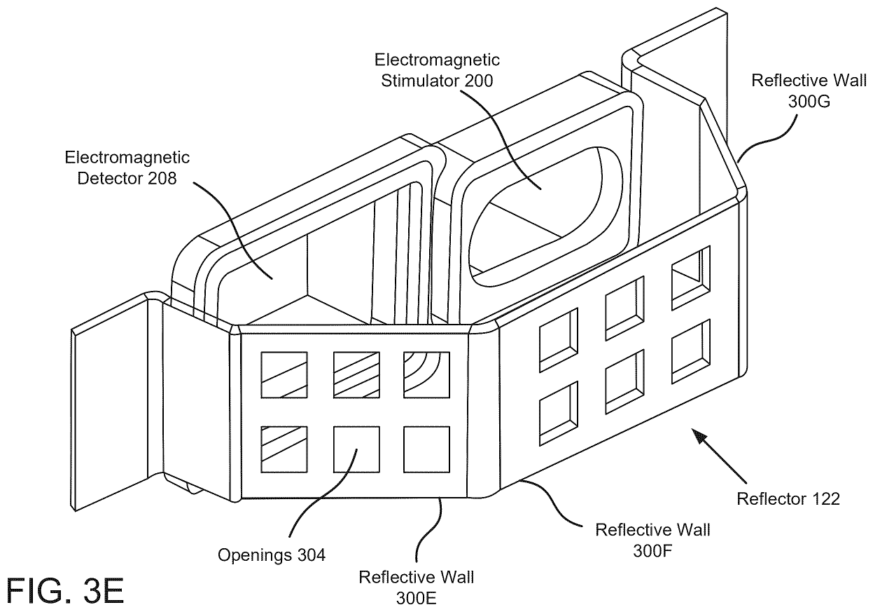

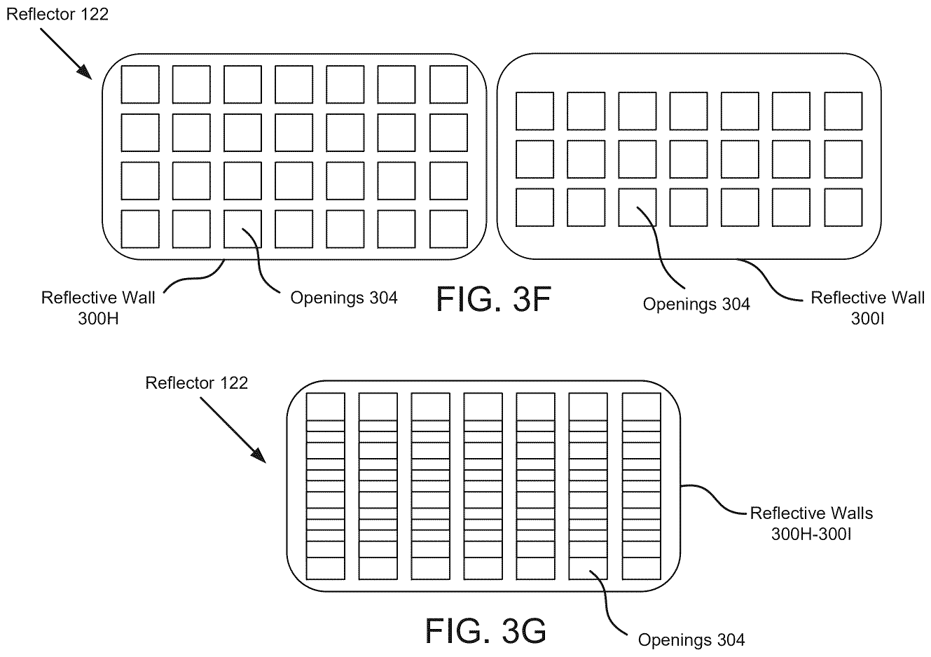

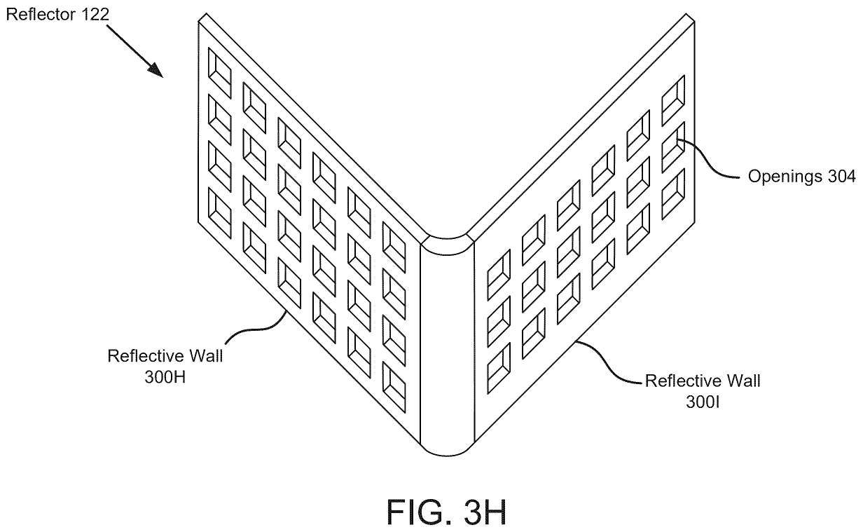

To improve a likelihood that the liquid leak is detected, leak detector 104 may include reflector 122. Reflector 122 may be adapted to: (i) collect the portion of the liquid within chassis 114, and (ii) direct the first electromagnetic radiation to the portion of the liquid. For example, reflector 122 may collect the portion of the liquid that has been aerosolized and which is entrained in airflow 118. Airflow 118 may traverse proximate to reflector 122, which may allow the portion of the liquid to condense on a portion of reflector 122. Reflector 122 may then direct the first electromagnetic radiation to the portion of the liquid. Refer to the description of FIG. 2A-3H for additional details regarding reflector 122.

By doing so, embodiments disclosed herein may improve a likelihood that the data processing system is able to provide computer-implemented services by increasing a likelihood of detecting a leak in the chassis of the data processing system. To do so, a reflector may be used to collect a portion of the liquid within the chassis, and direct first electromagnetic radiation generated by an electromagnetic stimulator to the portion of the liquid. The portion of the liquid may then generate second electromagnetic radiation. As a result, there may be an increased likelihood that an electromagnetic detector may be able to measure at least a portion of the second electromagnetic radiation. Consequently, the liquid leak may be detected, and actions may be performed so that additional leaked cooling liquid may be prevented from escaping into an interior of the chassis. In doing so, the likelihood of negatively impacting the hardware components, their functionalities, and the computer-implemented services that depend on these functionalities, may be reduced.

While illustrated in FIGS. 1A-1B with a limited number of specific components, a data processing system may include additional, fewer, and/or different components without departing from embodiments disclosed herein.

Turning to FIGS. 2A-2C, diagrams illustrating leak detector 104 in accordance with an embodiment are shown. FIGS. 2A-2B may show perspective view diagrams of leak detector 104. FIG. 2C may show a partially cutaway bottom view diagram of leak detector 104. Leak detector 104 may include electromagnetic stimulator 200, electromagnetic detector 208, reflector 122, and management component 224. Each of these components is discussed below.

Leak detector 104 may be positioned within a chassis of a data processing system in a portion of the chassis which has a risk of an occurrence of a liquid leak. For example, leak detector 104 may be positioned proximate to a liquid cooling tube joint and/or any other portion of the chassis for which leak detection is desired. In an instance of the occurrence of the liquid leak, a portion of the liquid (e.g., portion of liquid 210 shown in FIGS. 2B-2C), such as droplets, particles, and/or any other portion of the liquid, may interact with leak detector 104.

For example, as described above, the data processing system may include an airflow control component, such as a cooling fan, adapted to generate an airflow through the chassis. The airflow may entrain an aerosolized portion of the liquid (e.g., portion of liquid 210), and the airflow may traverse proximate to leak detector 104 in a manner which allows leak detector 104 to detect the liquid leak.

To detect the liquid leak, portion of liquid 210 may, for example, interact with reflector 122. Reflector 122 may be a component of leak detector 104, and may include at least one reflective wall. The at least one reflective wall may include any number, shape, and/or type of walls. The at least one reflective wall may or may not include any number and/or shape of openings. Refer to the description of FIGS. 3A-3H for additional details regarding the at least one reflective wall.

Reflector 122 may also be adapted to direct first electromagnetic radiation 202 (shown in FIGS. 2B-2C) to portion of liquid 210 (e.g., to predetermined location 212 in which portion of liquid 210 is positioned). First electromagnetic radiation 202 may be generated by electromagnetic stimulator 200, which may be a component of leak detector 104. Electromagnetic stimulator 200 may include any number and/or type of electromagnetic radiation sources adapted to generate first electromagnetic radiation 202 (e.g., light) of any wavelength and/or intensity. For example, electromagnetic stimulator 200 may include an ultraviolet (UV) light emitting diode (LED) lamp, and/or any other type of lamp.

To direct first electromagnetic radiation 202 to portion of liquid 210, the at least one reflective wall of reflector 122 may be positioned with respect to electromagnetic stimulator 200 so that at least a portion of first electromagnetic radiation 202 reflects off the at least one reflective wall. For example, the at least one reflective wall may be made from and/or coated with a material adapted to reflect first electromagnetic radiation 202. The at least one reflective wall may be positioned at an angle (e.g., angle 204 shown in FIG. 2C) with respect to electromagnetic stimulator 200 so that first electromagnetic radiation 202 is directed to portion of liquid 210. Angle 204 may be any angle which allows first electromagnetic radiation 202 to reflect off reflector 122 as desired.

For example, angle 204 may allow reflector 122 to be positioned with respect to electromagnetic stimulator 200 and electromagnetic detector 208 to prevent direct illumination of electromagnetic detector 208 by first electromagnetic radiation 202 (e.g., shown in FIG. 2C). For example, angle 204 may allow first electromagnetic radiation to be directed to portion of liquid 210, and may not allow first electromagnetic radiation 202 to be directed to electromagnetic detector 208.

Reflector 122 may be positioned to prevent direct illumination of electromagnetic detector 208 by first electromagnetic radiation 202 because illumination of electromagnetic detector 208 by first electromagnetic radiation 202 may reduce an ability of electromagnetic detector 208 to obtain measurements usable to determine whether a liquid leak has occurred. Thus, positioning reflector 122 at angle 204 may improve a likelihood of detecting the liquid leak.

First electromagnetic radiation 202 may be adapted to cause portion of liquid 210 to generate second electromagnetic radiation 206 (shown in FIGS. 2B-2C). For example, the liquid, and thus portion of liquid 210, may include a dye. The dye may include any type and quantity of dye, such as fluorescent organic dyes, etc. The properties of first electromagnetic radiation 202 (e.g., wavelength, intensity, etc.) may be selected based on characteristics of the dye included in the liquid to be detected. For example, the selected wavelength of first electromagnetic radiation 202 generated by electromagnetic stimulator 200 may interact with the dye in a desired manner. The interaction with the dye (e.g., excitation of electrons within the dye caused by absorbing a portion of first electromagnetic radiation 202) may cause the dye to generate second electromagnetic radiation 206 (e.g., fluorescence). Second electromagnetic radiation 206 may include electromagnetic radiation of any wavelength, intensity, and/or other characteristics based on properties of the dye which generates second electromagnetic radiation 206.

While described with respect to second electromagnetic radiation 206 being generated by a dye included in the liquid, it will be appreciated that other compounds and/or portions of the liquid may generate second electromagnetic radiation 206 without departing from embodiments disclosed herein.

To direct first electromagnetic radiation 202 to portion of the liquid 210, reflector 122 may be adapted to collect portion of liquid 210 within the chassis. To collect portion of liquid 210, the at least one reflective wall may be adapted to condense portion of liquid 210 on the at least one reflective wall. For example, the airflow entraining aerosolized portion of the liquid 210 may come into contact with the at least one reflective wall of reflector 122 (e.g., due to a path of the airflow traversing the at least one reflective wall of reflector 122). Upon contact, portion of liquid 210 may condense and deposit on the at least one reflective wall.

Collecting portion of liquid 210 by the at least one reflective wall of reflector 122 may also include directing portion of liquid 210 to a predetermined location (e.g., predetermined location 212). Predetermined location 212 may include: (i) a portion of a floor of the chassis proximate to electromagnetic detector 208 (e.g., as illustrated by the cloud shape in FIGS. 2B-2C), (ii) the at least one reflective wall of reflector 122 (e.g., as illustrated by the droplet shape in FIG. 2B), and/or (iii) other locations within the chassis.

Predetermined location 212 may be positioned with respect to electromagnetic stimulator 200 and electromagnetic detector 208 to: (i) receive first electromagnetic radiation 202, and (ii) direct a portion of second electromagnetic radiation 206 generated by portion of liquid 210 to electromagnetic detector 208. For example, receiving first electromagnetic radiation 202 by predetermined location 212 may include reflector 122 directing first electromagnetic radiation 202 to predetermined location 212 so that first electromagnetic radiation 202 illuminates portion of liquid 210. To direct the portion of second electromagnetic radiation 206 to electromagnetic detector 208, predetermined location 212 may be positioned proximate to electromagnetic detector 208 and/or angled with respect to electromagnetic detector 208 so that the portion of second electromagnetic radiation 206 is received and measured by electromagnetic detector 208.

At least a portion of second electromagnetic radiation 206 may be measured by electromagnetic detector 208 to obtain at least one electromagnetic measurement. Second electromagnetic radiation 206 may be measured by electromagnetic detector 208 because second electromagnetic radiation 206 may be usable to determine (e.g., by management component 224) whether the liquid leak occurred.

To obtain the at least one electromagnetic measurement, electromagnetic detector 208 may include any number and type of sensors 214. Sensors 214 may be adapted to measure electromagnetic radiation. For example, sensors 214 included as part of electromagnetic detector 208 may include photosensitive sensors adapted to measure wavelength, intensity, and/or other characteristics of electromagnetic radiation.

For example, sensors 214 may include a first sensor adapted to measure a red portion of second electromagnetic radiation 206, a second sensor adapted to measure a green portion of second electromagnetic radiation 206, and a third sensor adapted to measure a blue portion of second electromagnetic radiation 206. The at least one electromagnetic measurement may, in this example, include an intensity of the red portion measured by the first sensor, an intensity of the green portion measured by the second sensor, and an intensity of the blue portion measured by the third sensor.

Sensors 214 may be adapted to measure electromagnetic radiation within field of detection 218. Field of detection 218 may include any portion of the chassis from which sensors 214 are able to detect electromagnetic radiation. For example, to obtain the at least one electromagnetic measurement, at least a portion of second electromagnetic radiation may be directed to electromagnetic detector 208 by being positioned within field of detection 218. Reflector 122 may be positioned so that first electromagnetic radiation 202 is not directed to field of detection 218. Thus, the at least one electromagnetic measurement may include the at least the portion of second electromagnetic radiation 206, and may not include a portion of first electromagnetic radiation 202 directed from electromagnetic stimulator 200.

While described with respect to first electromagnetic radiation 202 not directly illuminating electromagnetic detector 208, it will be appreciated that a portion of first electromagnetic radiation 202 may be directed to electromagnetic detector 208 via unintended scattering within the chassis.

While illustrated as including three sensors, it will be appreciated that the electromagnetic detector may include any number of sensors without departing from embodiments disclosed herein.

Once obtained by electromagnetic detector 208, the at least one electromagnetic measurement may be provided to management component 224. Management component 224 may be adapted to determine whether the liquid leak within the chassis has occurred based on the at least one electromagnetic measurement. Management component 224 may include a management controller and/or other device of any type and/or including any quantity of components, such as a processing unit, that: (i) controls and/or monitors electromagnetic detector 208, (ii) obtains information regarding a status of electromagnetic detector 208, (iii) analyzes data (e.g., measurements) obtained by electromagnetic detector 208, and/or (iv) otherwise manages electromagnetic detector 208.

Management component 224 may make the determination regarding whether the liquid leak occurred by analyzing the at least one electromagnetic measurement. Analyzing the at least one electromagnetic measurement may include: (i) obtaining an electromagnetic spectrum using the at least one electromagnetic measurement, and/or (ii) comparing the electromagnetic spectrum to a known electromagnetic spectrum of the liquid. For example, a dye in a cooling liquid may generate second electromagnetic radiation 206 with a known electromagnetic spectrum when illuminated by first electromagnetic radiation 202. If the electromagnetic spectrum obtained based on the at least one electromagnetic measurement matches the known electromagnetic spectrum for the dye, management component 224 may determine that the liquid leak has occurred. If the electromagnetic spectrum obtained based on the at least one electromagnetic measurement does not match the known electromagnetic spectrum for the dye, management component 224 may determine that the liquid leak has not occurred.

If management component 224 determines that the liquid leak has occurred, management component 224 may initiate performance of a remediation action to mitigate impacts of the liquid leak. For example, management component 224 may: (i) notify a user of the data processing system via a graphical user interface that the liquid leak has occurred, (ii) generate an auditory notification indicating that the liquid leak has occurred, (iii) power off a portion of the hardware components of the data processing system (e.g., fans may be powered off to reduce spreading of the leak), and/or (iv) initiate performance of other remediation actions.

Any components of leak detector 104 may be positioned within the chassis of the data processing system using board 216. Board 216 may include any type of printed circuit board (e.g., flex, semi-flex) usable to provide a physical base for mounting and operably connecting the components of leak detector 104. For example, board 216 may allow components to be operably connected to management component 224 to allow management component 224 to manage operation of leak detector 104.

While illustrated in FIGS. 2A-2B with a limited number of specific components, a system may include additional, fewer, and/or different components without departing from embodiments disclosed herein.

Turning to FIGS. 3A-3H, diagrams illustrating a reflector (e.g., reflector 122) in accordance with an embodiment are shown. As discussed above, reflector 122 may be a component of a leak detector (e.g., leak detector 104, not shown) adapted to: (i) collect portion of liquid 210 within a chassis of a data processing system, and (ii) direct first electromagnetic radiation 202 generated by electromagnetic stimulator 200 to portion of liquid 210. Portion of liquid 210 may then generate second electromagnetic radiation 206, and at least a portion of second electromagnetic radiation 206 may be measured by electromagnetic detector 208.

To collect portion of liquid 210 and direct first electromagnetic radiation 202 to portion of liquid 210, reflector 122 may include reflective walls 300. Reflective walls 300 may include at least one reflective wall (e.g., 300A-300G). Reflective walls 300 may be positioned so that an airflow generated by an airflow control component traverses proximate to reflective walls 300. The airflow may entrain aerosolized portion of liquid 210, which may interact with reflective walls 300. As a result, portion of liquid 210 may condense on reflective walls 300.

Portion of liquid 210 may then be directed to a predetermined location (e.g., predetermined location 212), which may include a portion of the floor of the chassis and/or on reflective walls 300. Refer to the description of FIGS. 2A-2C for additional details regarding predetermined location 212.

Turning to FIG. 3A, reflector 122 may include reflective wall 300A and reflective wall 300B. Reflective wall 300A and reflective wall 300B may be positioned at different angles with respect to electromagnetic stimulator 200. By being positioned at the different angles, first electromagnetic radiation 202 may reflect off reflective wall 300A and reflective wall 300B at different angles, which may increase a likelihood that first electromagnetic radiation 202 illuminates portion of liquid 210 as desired. As a result, there may be an improved likelihood that second electromagnetic radiation 206 is generated by portion of liquid 210, and thus, that the liquid leak is detected.

For example, reflective wall 300A may be positioned perpendicular to the floor of the chassis. In contrast, reflective wall 300B may be angled towards the floor of the chassis. By including reflective wall 300B as part of reflector 122, an increased portion of first electromagnetic radiation 202 may be directed towards the floor of the chassis. An occurrence of a liquid leak within the chassis may result in liquid accumulating on the floor of the chassis. Thus, the inclusion of reflective wall 300B may improve a likelihood that first electromagnetic radiation 202 illuminates portion of liquid 210.

The inclusion of reflective wall 300B may also increase an amount of interaction between the airflow entraining aerosolized portion of liquid 210 and reflector 122 due to increased surface area of reflector 122. As a result, portion of liquid 210 collected by reflector 122 may include a larger amount of liquid (e.g., compared to if reflector 122 did not include reflective wall 300B), which may further increase a likelihood of detecting the liquid leak.

Turning to FIG. 3B, reflector 122 may include reflective wall 300C. Reflective wall 300C may include curved surface 302. Curved surface 302 may include a portion of reflective wall 300C which includes any number and/or type of convex and/or concave features. A direction and/or degree of curvature of the features may be used to manage a direction of various reflected portions of first electromagnetic radiation 202.

For example, curved surface 302 may be adapted to distribute two portions of first electromagnetic radiation 202 (e.g., first portion 310 and second portion 312) to two different regions within the chassis. The two different regions within the chassis may be physically separated from each other (e.g., the floor of the chassis and the ceiling of the chassis). For example, first portion 310 may be directed to the floor of the chassis towards a first portion of portion of liquid 210 which may have accumulated on the floor of the chassis. Second portion 312 may be directed to the ceiling of the chassis towards a second portion of portion of liquid 210 which may have accumulated on the ceiling of the chassis. Thus, by including curved surface 302 in reflector 122, a likelihood of first electromagnetic radiation 202 illuminating portion of liquid 210 may be increased.

Turning to FIGS. 3C-3D, reflector 122 may include reflective wall 300D. FIG. 3C may show a perspective view diagram of reflector 122. FIG. 3D may show a side view diagram of reflector 122.

Reflective wall 300D may include at least one opening (e.g., openings 304). Openings 304 may include any number of holes of any size and shape through reflective wall 300D. For example, openings 304 may be rectangular, circular, and/or any other shape. Openings 304 may allow an airflow to pass through reflective wall 300D. Thus, as a result of including openings 304 as part of reflector 122, airflow impedance due to the presence of reflector 122 may be reduced. Consequently, hardware components of the data processing system may continue to be cooled using the airflow as desired.

Openings 304 may be adapted to cause portion of liquid 210 to condense on at least edges of openings 304. For example, the airflow may include aerosolized portion of liquid 210, and upon traversing through openings 304, portion of liquid 210 may deposit on the edges of openings 304 (e.g., in addition to other portions of reflective wall 300D). Therefore, inclusion of openings 304 in reflective wall 300D may provide increased surface area on which portion of liquid 210 may condense, which may increase an amount of portion of liquid 210 which is collected by reflector 122. As a result, a likelihood of detecting the liquid leak may be improved.

The inclusion of openings 304 in reflective wall 300D may result in a portion of first electromagnetic radiation 202 being transmitted through reflective wall 300D (e.g., transmitted portion 306). However, openings 304 may be adapted to transmit a predetermined portion of first electromagnetic radiation 202 (e.g., transmitted portion 306) so that a reflected portion of first electromagnetic radiation 202 (e.g., reflected portion 308) meets a minimum threshold level.

Reflected portion 308 may be incident on portion of liquid 210 and may therefore be adapted to cause portion of liquid 210 to generate second electromagnetic radiation 206. Reflected portion 308 may be incident on portion of liquid 210 by illuminating a first portion of portion of liquid 210 that is positioned: (i) on reflective wall 300D, (ii) on a portion of the floor of the chassis, (iii) and/or any other location within the chassis.

The minimum threshold level may indicate an amount of reflected portion 308 required to cause portion of liquid 210 to generate a sufficient amount of second electromagnetic radiation 206 to be detected by electromagnetic detector 208. The amount of reflected portion 308 may be impacted by an availability of surface area of reflective wall 300D (e.g., portions of reflective wall 300D which do not include openings 304 and off which incident first electromagnetic radiation 202 may reflect). For example, the amount of reflected portion 308 may be impacted by: (i) a spacing between openings 304, (ii) a number of openings 304, and/or (iii) other features of reflective wall 300D which impacts available surface area off which first electromagnetic radiation 202 may reflect.

For example, electromagnetic stimulator 200 may generate first electromagnetic radiation 202 incident on reflective wall 300D. Reflective wall 300D may include openings 304 adapted to transmit 60% of first electromagnetic radiation 202. Therefore, transmitted portion 306 may include 60% of first electromagnetic radiation 202, and reflected portion 308 may include 40% of first electromagnetic radiation 202. The minimum threshold level may indicate that at least 35% of first electromagnetic radiation 202 is to be incident on portion of liquid 210 to cause portion of liquid 210 to generate a sufficient amount of second electromagnetic radiation 206 to be detected. Thus, in this example, reflected portion 308 may meet the minimum threshold level.

While described as a specific minimum threshold level, it will be appreciated that the minimum threshold level may include any criteria and/or threshold levels without departing from embodiments disclosed herein.

While illustrated in FIGS. 3C-3D as having a specific number and arrangement of openings 304, it will be appreciated that the at least one reflective wall of reflector 122 may include any number of openings of any shape, size, and arrangement without departing from embodiments disclosed herein.

Turning to FIG. 3E, reflector 122 may include a plurality of reflective walls (e.g., reflective wall 300E, reflective wall 300F, and reflective wall 300G). Reflective walls 300E-300G may include any number, size, and arrangement of openings 304 (and/or may not include openings 304). Reflective walls 300E-300G may be arranged to partially enclose a three-dimensional space around electromagnetic stimulator 200 and/or electromagnetic detector 208. Reflective walls 300E-300G may be in any arrangement and/or orientation to partially enclose the three-dimensional space of any size or shape.

By partially enclosing the three-dimensional space around electromagnetic stimulator 200 and/or electromagnetic detector 208, reflective walls 300E-300G may be adapted to: (i) increase a likelihood of first electromagnetic radiation 202 illuminating portion of liquid 210 (e.g., by providing more surface area off which first electromagnetic radiation 202 may reflect), (ii) increase an amount of portion of liquid 210 which is collected by reflector 122 (e.g., by providing more surface area on which aerosolized portion of liquid 210 may condense), (iii) increase a likelihood that second electromagnetic radiation 206 generated by portion of liquid 210 is directed to electromagnetic detector 208 (e.g., by providing more surface area off which the second electromagnetic radiation may reflect), and/or (iv) otherwise improve a likelihood that the liquid leak is detected.

Reflective walls 300E-300G may further improve a likelihood that the liquid leak is detected by being adapted to direct portion of liquid 210 to the predetermined location within the three-dimensional space. For example, upon condensing, for example, on at least the edges of openings 304, portion of liquid 210 may flow to a portion of the floor of the chassis within the three-dimensional space, which may be proximate to electromagnetic stimulator 200 and electromagnetic detector 208. In doing so, first electromagnetic radiation 202 may be directed to portion of liquid 210 and second electromagnetic radiation 206 may be directed to electromagnetic detector 208.

While illustrated as the plurality of reflective walls including three reflective walls arranged to partially enclose the three-dimensional space, it will be appreciated that the plurality of reflective walls may include any number of reflective walls without departing from embodiments disclosed herein.

Turning to FIGS. 3F-3H, reflector 122 may include a plurality of reflective walls (e.g., reflective wall 300H, reflective wall 300I). FIG. 3F may illustrate a front view of reflective wall 300H and reflective wall 300I. FIG. 3G may illustrate an overlapping view of reflective walls 300H-300I, which may represent a perspective of electromagnetic stimulator 200. FIG. 3H may illustrate a perspective view of an example arrangement of reflective walls 300H-300I.

Reflective walls 300H-300I may include openings 304, which may be arranged in a manner that results in openings 304 on reflective wall 300H being offset from openings 304 on reflective wall 300I.

For example, as shown in FIG. 3F, openings 304 may be arranged in rows. The rows of openings 304 on reflective wall 300H may be offset from the rows of openings 304 on reflective wall 300I (e.g., the rows of openings 304 on reflective wall 300H may not align with the rows of openings 304 on reflective wall 300I). It will be appreciated that openings 304 may be arranged in any other manner which allows openings 304 on a first reflective wall to be offset from openings 304 on a second reflective wall.

Reflective walls 300H-300I may be positioned with respect to electromagnetic stimulator 200 so that first electromagnetic radiation 202 generated by electromagnetic stimulator 200 illuminates both reflective walls 300H-300I (as shown in FIGS. 3G-3H). As a result, there may be a higher density of available surface area off which first electromagnetic radiation 202 may reflect. Consequently, a likelihood of first electromagnetic radiation 202 illuminating portion of liquid 210 as desired may be improved.

While illustrated in FIGS. 3A-3H with a limited number of specific components, a system may include additional, fewer, and/or different components without departing from embodiments disclosed herein.

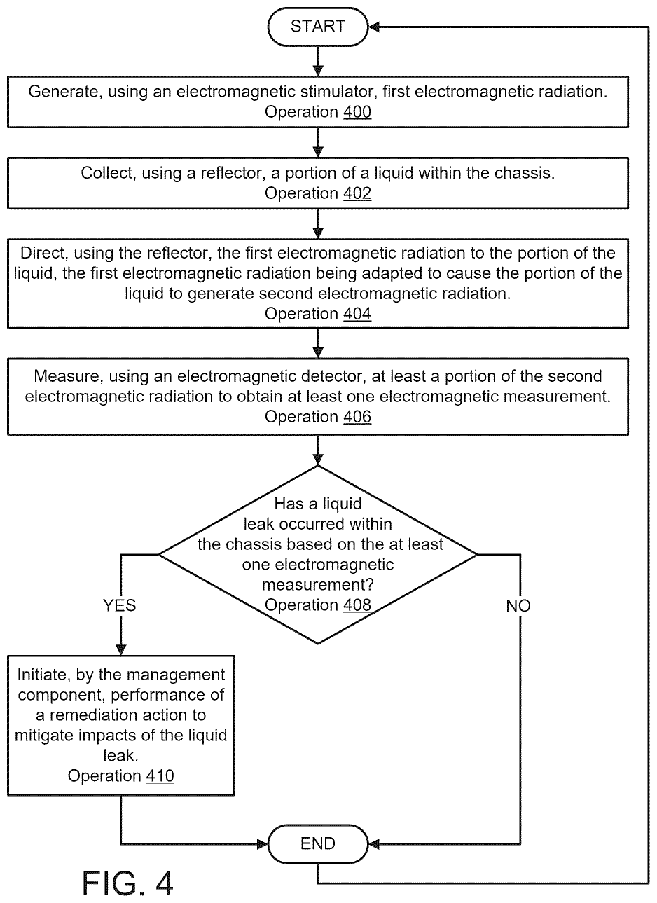

As discussed above, the components of FIGS. 1A-3H may perform various methods to manage leaks in a chassis of a data processing system. FIG. 4 illustrates a method that may be performed by the components of the system of FIGS. 1A-3H. In the diagram discussed below and shown in FIG. 4, any of the operations may be repeated, performed in different orders, and/or performed in parallel with or in a partially overlapping in a timely manner with other operations. The method described with respect to FIG. 4 may be performed by a data processing system, any component of a data processing system, and/or another device.

Turning to FIG. 4, a flow diagram illustrating a method in accordance with an embodiment is shown. The flow diagram may illustrate various operations performed while managing leaks in a chassis of a data processing system. The data processing system may be similar to the data processing system discussed with respect to FIGS. 1A-1B.

At operation 400, first electromagnetic radiation may be generated using an electromagnetic stimulator. Generating the first electromagnetic radiation may include: (i) powering an electromagnetic radiation source of the electromagnetic stimulator, (ii) emitting the first electromagnetic radiation by the electromagnetic stimulator, and/or (iii) other methods.

At operation 402, a portion of a liquid within the chassis may be collected using a reflector. Collecting the portion of the liquid may include: (i) positioning the reflector within the chassis so that an airflow entraining the portion of the liquid traverses proximate to the reflector, (ii) condensing the portion of the liquid on at least one reflective wall of the reflector, (iii) directing the portion of the liquid to a predetermined location (e.g., flowing the portion of the liquid to a portion of the floor of the chassis and/or any other predetermined location), and/or (iv) other methods.

At operation 404, the first electromagnetic radiation may be directed to the portion of the liquid using the reflector, the first electromagnetic radiation being adapted to cause the portion of the liquid to generate second electromagnetic radiation. Directing the first electromagnetic radiation to the portion of the liquid may include: (i) positioning the reflector so that an angle of reflection of the first portion of the electromagnetic radiation causes the first portion of the electromagnetic radiation to illuminate the portion of the liquid as desired, (ii) positioning the reflector so that the portion of the liquid condensed on the at least one reflected wall is illuminated by the first electromagnetic radiation, (iii) illuminating the reflector using the first electromagnetic radiation, and/or (iv) other methods.

At operation 406, at least a portion of the second electromagnetic radiation may be measured using an electromagnetic detector to obtain at least one electromagnetic measurement. Measuring the at least the portion of the second electromagnetic radiation may include: (i) receiving the second electromagnetic radiation by the electromagnetic detector, (ii) performing an analysis process by the electromagnetic detector to obtain the at least one electromagnetic measurement (e.g., determining an intensity of the second electromagnetic radiation for a wavelength and/or range of wavelengths to obtain the at least one electromagnetic measurement, using the intensity to obtain an electromagnetic spectrum for the second electromagnetic radiation), and/or (iii) other methods.

At operation 408, a determination may be made by a management component regarding whether a liquid leak within the chassis has occurred based on the at least one electromagnetic measurement. Making the determination may include: (i) obtaining, by the management component, the electromagnetic spectrum for the second electromagnetic radiation using the at least one electromagnetic measurement, (ii) comparing the electromagnetic spectrum to a known electromagnetic spectrum for the liquid (e.g., a dye included in the liquid) to obtain a result, (iii) providing the electromagnetic spectrum to another entity and receiving an indication of whether the liquid leak has occurred in response, and/or (iv) other methods.

For example, if the result indicates that the electromagnetic spectrum matches the known electromagnetic spectrum for the liquid, the management component may determine that the liquid leak has occurred. In another example, if the result indicates that the electromagnetic spectrum does not match the known electromagnetic spectrum for the liquid, the management component may determine that the liquid leak has not occurred.

If it is determined that the liquid leak has occurred within the chassis (e.g., the determination is “Yes” at operation 408), then the method may proceed to operation 410.

At operation 410, the management component may initiate performance of a remediation action to mitigate impacts of the liquid leak. Initiating performance of the remediation action may include: (i) notifying a user of the data processing system via a graphical user interface that the liquid leak has occurred, (ii) powering a speaker to generate an auditory notification indicating that the liquid leak has occurred, (iii) powering off a portion of the hardware components of the data processing system (e.g., fans may be powered off to reduce spreading of the leak, electrical components may be powered off to reduce damage), and/or (iv) other methods.

The method may end following operation 410.

Returning to operation 408, if it is determined that the liquid leak has not occurred within the chassis (e.g., the determination is “No” at operation 408), then the method may end. The data processing system may continue to provide computer-implemented services as desired.

The method may subsequently be repeated any number of times. In doing so, the chassis may continue to be monitored for an occurrence of a liquid leak.

Thus, embodiments disclosed herein may address, among others, the technical challenge of mitigating risks associated with using a cooling liquid to provide thermal management services for a data processing system. To do so, the data processing system may include a leak detector, which may include a reflector. The reflector may be adapted to: (i) collect a portion of a liquid (e.g. cooling liquid) within the chassis, and (ii) direct first electromagnetic radiation generated by an electromagnetic stimulator to the portion of the liquid. At least a portion of second electromagnetic radiation generated by the portion of the liquid may then be measured using an electromagnetic detector. As a result of the collecting and the directing by the reflector, a likelihood that the liquid leak may be detected may be improved. If the liquid leak has occurred, a remediation action may be performed. Thus, a likelihood of the liquid leak negatively impacting hardware functionality may be decreased and may in turn decrease a likelihood of negatively impacting computer-implemented services provided by the data processing system.

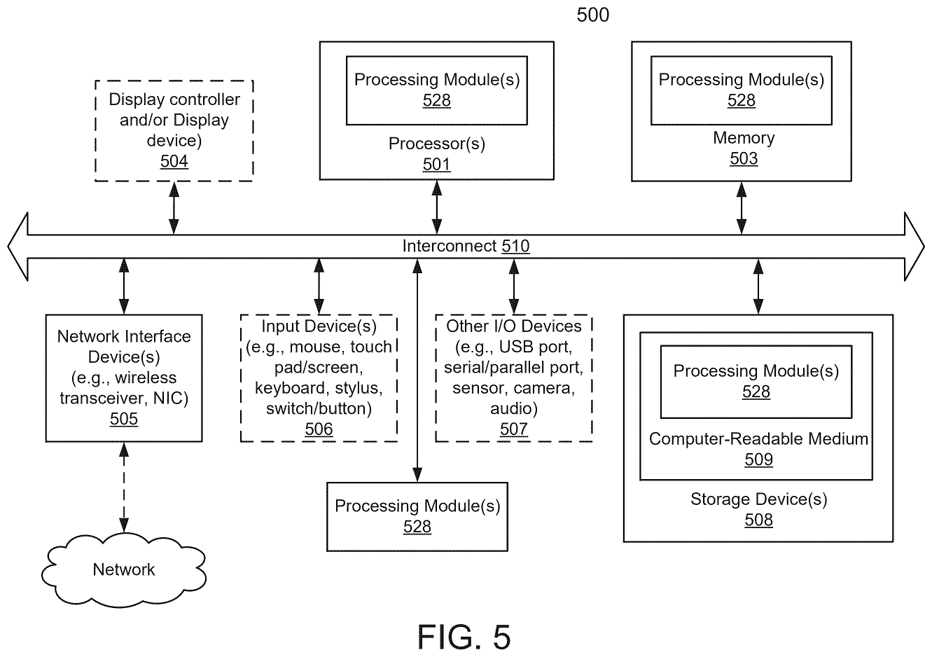

Any of the components and methods illustrated in FIGS. 1-4 may be implemented with one or more computing devices. Turning to FIG. 5, a block diagram illustrating an example of a data processing system (e.g., a computing device) in accordance with an embodiment is shown. For example, system 500 may represent any of data processing systems described above performing any of the processes or methods described above. System 500 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 500 is intended to show a high level view of many components of the computer system. However, it is to be understood that additional components may be present in certain implementations and furthermore, different arrangement of the components shown may occur in other implementations. System 500 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 500 includes processor 501, memory 503, and devices 505-507 via a bus or an interconnect 510. Processor 501 may represent a single processor or multiple processors with a single processor core or multiple processor cores included therein. Processor 501 may represent one or more general-purpose processors such as a microprocessor, a central processing unit (CPU), or the like. More particularly, processor 501 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 501 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 501, which may be a low power multi-core processor socket such as an ultra-low voltage processor, may act as a main processing unit and central hub for communication with the various components of the system. Such processor can be implemented as a system on chip (SoC). Processor 501 is configured to execute instructions for performing the operations discussed herein. System 500 may further include a graphics interface that communicates with optional graphics subsystem 504, which may include a display controller, a graphics processor, and/or a display device.

Processor 501 may communicate with memory 503, which in one embodiment can be implemented via multiple memory devices to provide for a given amount of system memory. Memory 503 may include one or more volatile storage (or memory) devices such as random access memory (RAM), dynamic RAM (DRAM), synchronous DRAM (SDRAM), static RAM (SRAM), or other types of storage devices. Memory 503 may store information including sequences of instructions that are executed by processor 501, or any other device. For example, executable code and/or data of a variety of operating systems, device drivers, firmware (e.g., input output basic system or BIOS), and/or applications can be loaded in memory 503 and executed by processor 501. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 500 may further include IO devices such as devices (e.g., 505, 506, 507, 508) including network interface device(s) 505, optional input device(s) 506, and other optional IO device(s) 507. Network interface device(s) 505 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 506 may include a mouse, a touch pad, a touch sensitive screen (which may be integrated with a display device of optional graphics subsystem 504), a pointer device such as a stylus, and/or a keyboard (e.g., physical keyboard or a virtual keyboard displayed as part of a touch sensitive screen). For example, input device(s) 506 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 507 may include an audio device. An audio device may include a speaker and/or a microphone to facilitate voice-enabled functions, such as voice recognition, voice replication, digital recording, and/or telephony functions. Other IO devices 507 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 507 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 510 via a sensor hub (not shown), while other devices such as a keyboard or thermal sensor may be controlled by an embedded controller (not shown), dependent upon the specific configuration or design of system 500.

To provide for persistent storage of information such as data, applications, one or more operating systems and so forth, a mass storage (not shown) may also couple to processor 501. In various embodiments, to enable a thinner and lighter system design as well as to improve system responsiveness, this mass storage may be implemented via a solid state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also a flash device may be coupled to processor 501, e.g., via a serial peripheral interface (SPI). This flash device may provide for non-volatile storage of system software, including a basic input/output software (BIOS) as well as other firmware of the system.

Storage device 508 may include computer-readable storage medium 509 (also known as a machine-readable storage medium or a computer-readable medium) on which is stored one or more sets of instructions or software (e.g., processing module, unit, and/or processing module/unit/logic 528) embodying any one or more of the methodologies or functions described herein. Processing module/unit/logic 528 may represent any of the components described above. Processing module/unit/logic 528 may also reside, completely or at least partially, within memory 503 and/or within processor 501 during execution thereof by system 500, memory 503 and processor 501 also constituting machine-accessible storage media. Processing module/unit/logic 528 may further be transmitted or received over a network via network interface device(s) 505.

Computer-readable storage medium 509 may also be used to store some software functionalities described above persistently. While computer-readable storage medium 509 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 528, components and other features described herein can be implemented as discrete hardware components or integrated in the functionality of hardware components such as ASICS, FPGAs, DSPs or similar devices. In addition, processing module/unit/logic 528 can be implemented as firmware or functional circuitry within hardware devices. Further, processing module/unit/logic 528 can be implemented in any combination hardware devices and software components.

Note that while system 500 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A data processing system, comprising:
a chassis;
an electromagnetic stimulator adapted to generate first electromagnetic radiation;
a reflector adapted to:
collect a portion of a liquid within the chassis, and
direct the first electromagnetic radiation to the portion of the liquid, the first electromagnetic radiation being adapted to cause the portion of the liquid to generate second electromagnetic radiation;
an electromagnetic detector adapted to:
measure at least a portion of the second electromagnetic radiation to obtain at least one electromagnetic measurement; and
a management component adapted to:
make a determination regarding whether a liquid leak within the chassis has occurred based on the at least one electromagnetic measurement; and
in an instance of the determination where the liquid leak has occurred:
initiate performance of a remediation action to mitigate impacts of the liquid leak.

2. The data processing system of claim 1, wherein the reflector is positioned with respect to the electromagnetic stimulator and the electromagnetic detector to prevent direct illumination of the electromagnetic detector by the first electromagnetic radiation.

3. The data processing system of claim 1, wherein the reflector comprises at least one reflective wall.

4. The data processing system of claim 3, wherein the at least one reflective wall comprises at least one opening, and the at least one opening is adapted to:
allow an airflow to pass through the at least one reflective wall; and
transmit a predetermined portion of the first electromagnetic radiation so that a reflected portion of the first electromagnetic radiation meets a minimum threshold level, the reflected portion being incident on the portion of the liquid.

5. The data processing system of claim 3, wherein the at least one reflective wall comprises a curved surface adapted to distribute two portions of the first electromagnetic radiation to two different regions within the chassis, the two different regions being physically separated from each other.

6. The data processing system of claim 3, wherein the at least one reflective wall is adapted to:
condense the portion of the liquid on the at least one reflective wall; and
direct the portion of the liquid to a predetermined location to collect the portion of the liquid.

7. The data processing system of claim 6, wherein the predetermined location is positioned with respect to the electromagnetic stimulator and the electromagnetic detector to:
receive the first electromagnetic radiation; and
direct the at least the portion of the second electromagnetic radiation generated by the portion of the liquid to the electromagnetic detector.

8. The data processing system of claim 7, wherein the predetermined location is a portion of a floor of the chassis proximate to the electromagnetic detector.

9. The data processing system of claim 6, wherein the at least one reflective wall comprises at least one opening adapted to cause the portion of the liquid to condense on at least edges of the at least one opening.

10. The data processing system of claim 6, wherein the reflector comprises a plurality of reflective walls, and the plurality of reflective walls are arranged to partially enclose a three-dimensional space around the electromagnetic stimulator and the electromagnetic detector.

11. The data processing system of claim 10, wherein the plurality of reflective walls is adapted to direct the portion of the liquid to the predetermined location within the three-dimensional space.

12. The data processing system of claim 1, further comprising:
a liquid cooling block adapted to cool a hardware component using the liquid,
wherein the portion of the liquid is aerosolized during the collecting by the reflector.

13. The data processing system of claim 12, further comprising:
an airflow control component adapted to generate an airflow through the chassis, the airflow entraining the aerosolized portion of the liquid, and the airflow traversing proximate to the reflector.

14. A method for managing leaks in a chassis of a data processing system, the method comprising:
generating, using an electromagnetic stimulator, first electromagnetic radiation;
collecting, using a reflector, a portion of a liquid within the chassis;
directing, using the reflector, the first electromagnetic radiation to the portion of the liquid, the first electromagnetic radiation being adapted to cause the portion of the liquid to generate second electromagnetic radiation;
measuring, using an electromagnetic detector, at least a portion of the second electromagnetic radiation to obtain at least one electromagnetic measurement;
making, by a management component, a determination regarding whether a liquid leak within the chassis has occurred based on the at least one electromagnetic measurement; and
in an instance of the determination where the liquid leak has occurred:
initiating, by the management component, performance of a remediation action to mitigate impacts of the liquid leak.

15. The method of claim 14, wherein the reflector is positioned with respect to the electromagnetic stimulator and the electromagnetic detector to prevent direct illumination of the electromagnetic detector by the first electromagnetic radiation.

16. The method of claim 14, wherein the reflector comprises at least one reflective wall.

17. The method of claim 16, wherein the at least one reflective wall comprises at least one opening, and the at least one opening is adapted to:
allow an airflow to pass through the at least one reflective wall; and
transmit a predetermined portion of the first electromagnetic radiation so that a reflected portion of the first electromagnetic radiation meets a minimum threshold level, the reflected portion being incident on the portion of the liquid.

18. The method of claim 16, wherein the at least one reflective wall comprises a curved surface adapted to distribute two portions of the first electromagnetic radiation to two different regions within the chassis, the two different regions being physically separated from each other.

19. The method of claim 16, wherein the at least one reflective wall is adapted to:
condense the portion of the liquid on the at least one reflective wall; and
direct the portion of the liquid to a predetermined location to collect the portion of the liquid.

20. The method of claim 19, wherein the predetermined location is positioned with respect to the electromagnetic stimulator and the electromagnetic detector to:
receive the first electromagnetic radiation; and
direct the at least the portion of the second electromagnetic radiation generated by the portion of the liquid to the electromagnetic detector.
